(19) United States
(12) Patent Application Publication
(10) Pub. No.: US 2026/0035208 A1
(43) Pub. Date: Feb. 5, 2026

(54) CONVEYANCE DEVICE

(71) Applicant: DAIFUKU CO., LTD., Osaka (JP)

(72) Inventors: Takato MATSUO, Shiga (JP); Jyunichi SAKAMOTO, Shiga (JP); Ryoji MORISHITA, Shiga (JP)

(73) Assignee: DAIFUKU CO., LTD., Osaka (JP)

(21) Appl. No.: 19/259,153

(22) Filed: Jul. 3, 2025

(30) Foreign Application Priority Data
Aug. 5, 2024 (JP) 2024-129147

(51) Int. Cl. B66B 7/06; B66B 7/04; B66B 17/12

(52) U.S. Cl. CPC B66B 7/064; B66B 7/046; B66B 17/12

(57) ABSTRACT

The present disclosure provides a conveyance device improved in arrangement of a power receiving section with respect to a mast. An article conveyance device includes: a mast including a first side section and a second side section that are located opposite to each other; a power receiving section disposed between the first side section and the second side section; and a feed line configured to supply power to the power receiving section. The first side section and the second side section each include a wiring path through which the feed line passes.

This Nonprovisional application claims priority under 35 U.S.C. § 119 on Patent Application No. 2024-129147 filed in Japan on Aug. 5, 2024, the entire contents of which are hereby incorporated by reference.

### TECHNICAL FIELD

The present disclosure relates to a conveyance device.

### BACKGROUND ART

Conventionally, a conveyance device has been known which conveys an article across floors and transfer the article to and from a delivery conveyance device on each floor. With respect to this type of conveyance device, for example, Patent Literature 1 discloses a configuration in which a carriage (elevator member) that is raised and lowered along a mast is provided with a power receiving section that receives driving power.

### CITATION LIST

### Patent Literature

### Patent Literature 1

Japanese Patent Application Publication Tokukai No. 2018-039664

### SUMMARY OF INVENTION

### Technical Problem

However, the conventional configuration is such that the power receiving section that is raised and lowered together with the carriage is disposed outside the mast and is exposed, and thus has room for improvement in the arrangement of the power receiving section.

It is an object of an aspect of the present disclosure to provide a conveyance device improved in arrangement of a power receiving section with respect to a mast.

### Solution to Problem

In order to solve the foregoing problem, a conveyance device in accordance with an aspect of the present disclosure includes: a mast including a first side section and a second side section that are located opposite to each other; an elevator section that is provided so as to be raisable and lowerable with respect to the mast and that conveys an article; a power receiving section that is disposed between the first side section and the second side section and that is raised and lowered together with the elevator section; and a feed line that is disposed along the mast and that supplies power to the power receiving section, at least one of the first side section and the second side section including a wiring path through which the feed line passes.

### Advantageous Effects of Invention

An aspect of the present disclosure makes it possible to provide a conveyance device improved in arrangement of a power receiving section with respect to a mast.

### BRIEF DESCRIPTION OF DRAWINGS

FIG. 1 is a perspective view illustrating conveyance equipment in accordance with an embodiment.

FIG. 2 is a plan view illustrating an internal configuration of a tubular body illustrated in FIG. 1.

FIG. 3 is a plan view illustrating a configuration of a main part of an article conveyance device illustrated in FIG. 2.

FIG. 4 is a plan view illustrating a configuration of the main part of the article conveyance device and illustrating the wiring of bypass wiring sections.

FIG. 5 is a plan view illustrating a configuration in which tubular sections are attached to wiring paths illustrated in FIG. 4.

### DESCRIPTION OF EMBODIMENTS

The following description will discuss an embodiment of the present disclosure. It should be noted that the following description will discuss one example of a conveyance device in accordance with the present disclosure, and the technical scope of the present disclosure is not limited to the illustrated examples.

### [Overall Configuration of Conveyance Equipment]

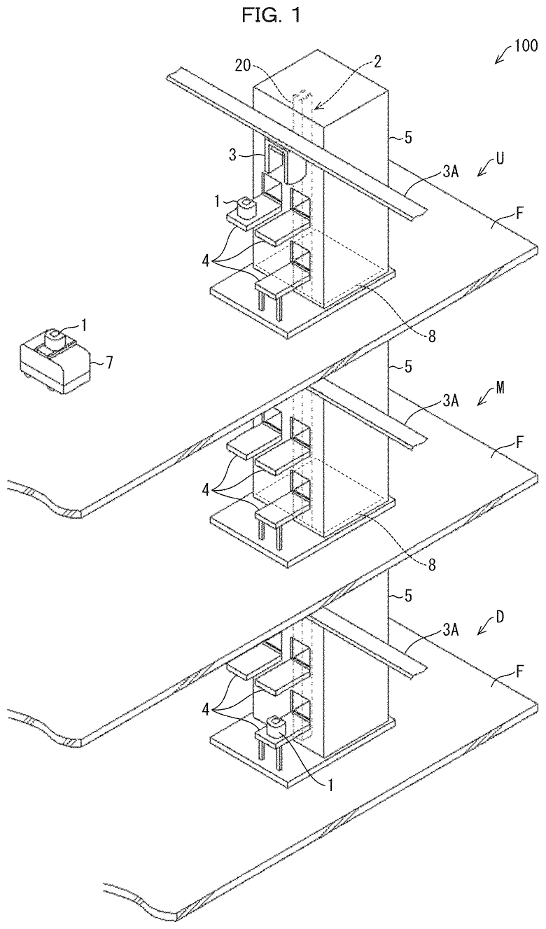

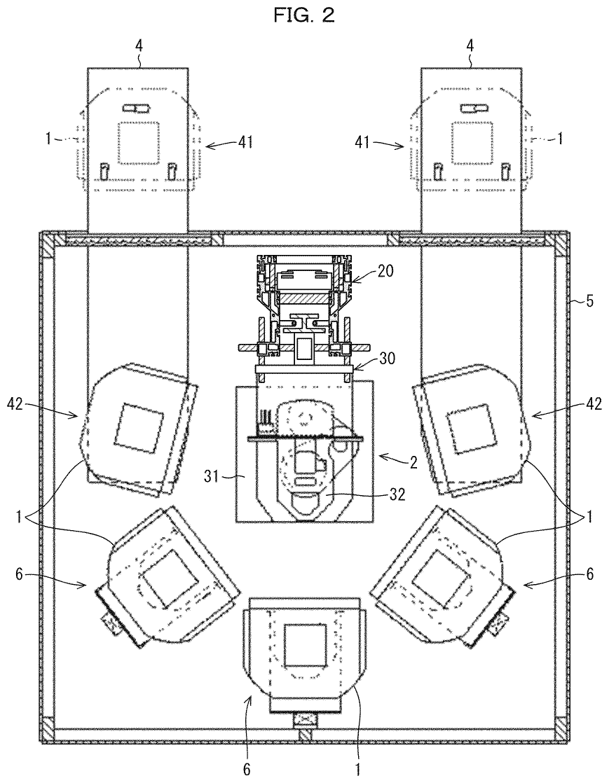

First, the following description will discuss an overall configuration of conveyance equipment 100 in accordance with the present embodiment. FIG. 1 is a perspective view illustrating the conveyance equipment 100 in accordance with the present embodiment. FIG. 2 is a plan view illustrating the interior of a tubular body 5 illustrated in FIG. 1.

As illustrated in FIG. 1 and FIG. 2, the conveyance equipment 100 is provided with an article conveyance device (conveyance device) 2 configured to convey a container 1 as an article across a plurality of floors (which are, in the present embodiment, three floors and are referred to as “upper floor U”, “middle floor M”, and “lower floor D” in order from the top floor). The article conveyance device 2 is an inter-floor conveyance device configured to convey the container 1 across floors.

Further, the conveyance equipment 100 is provided with a ceiling carrier 3 configured to travel along a travelling rail 3A provided in the vicinity of a ceiling of each floor to convey the container 1, a floor carrier 7 configured to travel on the floor surface F on each floor to convey the container 1, and loading-unloading conveyance devices 4 that are disposed in the tubular body 5 accommodating the article conveyance device 2 and that each convey the container 1. The container 1 may be, for example, a front opening unified pod (FOUP) accommodating a semiconductor substrate as an article.

Inside the tubular body 5, the article conveyance device 2 is disposed from the upper floor U to the lower floor D. In addition, the ceiling carrier 3 and the floor carrier 7 are disposed outside the tubular body 5. The loading-unloading conveyance devices 4 are disposed from the inside to outside of the tubular body 5, and each convey the container 1 between an outside portion 41 located outside the tubular body 5 and an inside portion 42 located inside the tubular body 5.

The tubular body 5 is provided therein with a raising and lowering movement path along which an elevator section 30 of the article conveyance device 2 is raised and lowered. In the present embodiment, the tubular body 5 is composed of three divided portions: a portion provided on the upper floor U, a portion provided on the middle floor M, and a portion provided on the lower floor D. Openings (not illustrated) through which the elevator section 30 of the article conveyance device 2 passes are formed on the floor surface F of the upper floor U and on the floor surface F of the middle floor M. This allows formation of the raising and lowering movement path communicating from the upper floor U to the lower floor D.

Inside the tubular body 5, the article conveyance device 2 and a plurality of accommodation sections 6 each for accommodating the container 1 are disposed (see FIG. 2). The article conveyance device 2 includes a mast 20 extending in an up-and-down direction and the elevator section 30 that is provided so as to be raisable and lowerable in an up-and-down direction with respect to the mast 20 and that conveys the container 1. The elevator section 30 has a loading space 31 to which a transferring section 32 configured to transfer the container 1 to an accommodation section 6 is mounted. Accommodation sections 6 are provided side by side in a circumferential direction around the transferring section 32 in a plan view, and further a plurality of accommodation sections 6 are disposed in the up-and-down direction.

Further, the conveyance equipment 100 is provided with openable and closable fireproof doors 8 located between adjacent floors and configured to cross the raising and lowering movement path of the elevator section 30 to block the inside of the tubular body 5 (see FIG. 1). The fireproof doors 8 are made of, for example, iron, and in the present embodiment, the fireproof doors 8 are provided horizontally between the upper floor U and the middle floor M and between the middle floor M and the lower floor D. A configuration is employed of closing the openings formed on the floor surfaces F with use of the fireproof doors 8 to block the inside of the tubular body 5.

With the conveyance equipment 100 having the configuration described above, when the container 1 is placed on the outside portion 41 of a loading-unloading conveyance device 4 by the ceiling carrier 3, the floor carrier 7, or an operator, the container 1 is conveyed by the loading-unloading conveyance device 4 from the outside portion 41 to the inside portion 42. Then, the container 1 is conveyed by the article conveyance device 2 from the inside portion 42 to an accommodation section 6 and is accommodated in the accommodation section 6.

The container 1 accommodated in the accommodation section 6 is conveyed by the article conveyance device 2 from the accommodation section 6 to the inner portion 42 of the loading-unloading conveyance device 4, and then the container 1 is conveyed and placed from the inside portion 42 onto the outside portion 41 by the loading-unloading conveyance device 4. The container 1 on the outside portion 41 is then unloaded from the outside portion 41 by the ceiling carrier 3, the floor carrier 7, or an operator.

### [Configuration of Article Conveyance Device]

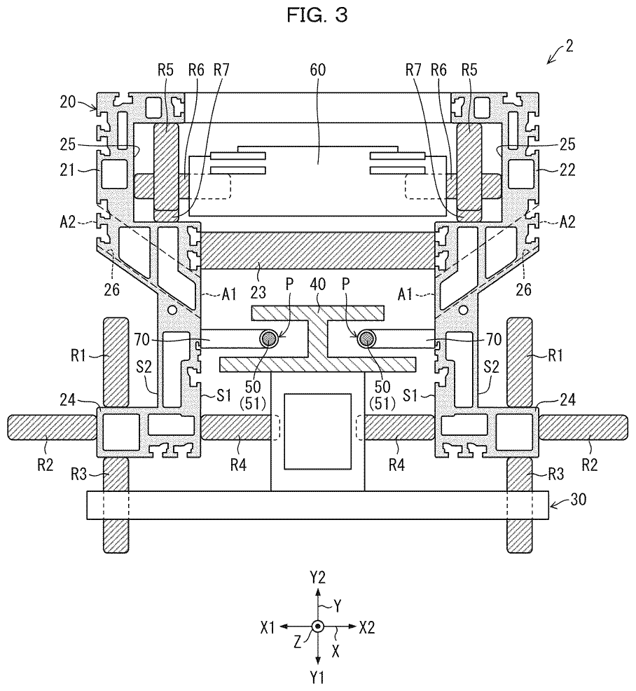

Next, the following description will discuss a configuration of the article conveyance device 2. FIG. 3 is a plan view illustrating a configuration of a main part of the article conveyance device 2 illustrated in FIG. 2. In the following description, as illustrated in FIG. 3, a direction in which the mast 20 and the elevator section 30 are arranged when viewed from an up-and-down direction Z in which the mast 20 extends may be referred to as “front-and-rear direction Y”, a direction in which the elevator section 30 is located with respect to the mast 20 in the front-and-rear direction Y when viewed from the up-and-down direction Z may be referred to as “front direction Y1”, and the direction opposite to the front direction Y1 when viewed from the up-and-down direction Z may be referred to as “rear direction Y2” Further, a direction in which a first side section 21 and a second side section 22 are located opposite to each other when viewed from the front direction Y1 may be referred to as “left-and-right direction (width direction) X”, the direction toward a first side section 21 side of the left-and-right direction X when viewed from the front direction Y1 may be referred to as “left direction X1”, and the direction toward a second side section 22 side of the left-and-right direction X when viewed from the front direction Y1 may be referred to as “right direction X2”.

As illustrated in FIG. 3, the article conveyance device 2 includes the mast 20 extending in the up-and-down direction Z and the elevator section 30 that is provided so as to be raisable and lowerable with respect to the mast 20 and that conveys the container 1.

Further, the article conveyance device 2 includes a power receiving section 40 disposed inside the mast 20 and feed lines 50 disposed along the mast 20 in the up-and-down direction Z. The power receiving section 40 is connected to the elevator section 30 and is raised and lowered together with the elevator section 30. The feed line 50 is disposed in the mast 20 in the vicinity of the power receiving section 40 and supplies power to the power receiving section 40 without contact.

Further, the article conveyance device 2 includes a counterweight (balance weight) 60 disposed opposite from the elevator section 30 with the power receiving section 40 interposed therebetween in a plan view. The counterweight 60 is connected to the elevator section 30 via a wire wound around a rotating body (not illustrated) provided above the raising and lowering movement path.

The mast 20 is a guide rail for guiding the raising and lowering movement of the elevator section 30. The mast 20 has a first side section 21 and a second side section 22 that are located opposite to each other in the left-and-right direction X; and a coupling section 23 coupling the first side section 21 and the second side section 22.

The first side section 21 and the second side section 22 are made of, for example, aluminum and include respective inner side surfaces S1 facing each other and respective outer side surfaces S2 located opposite to the inner side surfaces S1. The coupling section 23 is disposed between the first side section 21 and the second side section 22, and couples the inner side surfaces S1 of the first side section 21 and the second side section 22 in the vicinity of a center portion in the front-and-rear direction Y.

In the first side section 21 and the second side section 22, respective protruding sections 24 protruding outward (toward an outer side surface S2 side) in the left-and-right direction X from end portions of the outer side surfaces S2 on a front direction Y1 side are continuously formed in the up-and-down direction Z. Each of the protruding sections 24 has a rectangular shape in a plan view. On the protruding section 24, a first guide roller R1, a second guide roller R2, and a third guide roller R3 each for guiding the raising and lowering movement of the elevator section 30 abut from three directions.

Specifically, the first guide roller R1 abuts on the outer side surface S2 of the protruding section 24 on a rear direction Y2 side. The second guide roller R2 abuts on the outer side surface S2 of the protruding section 24 on an outer side in the left-and-right direction X. The third guide roller R3 abuts on the outer side surface S2 of the protruding section 24 on a front direction Y1 side. As such, the first guide roller R1, the second guide roller R2, and the third guide roller R3 are disposed outside the mast 20. This improves maintainability in inspection and replacement of these guide rollers R1, R2, and R3.

A fourth guide roller R4 for guiding the raising and lowering movement of the elevator section 30 abuts on each of the inner side surfaces S1 of the first side section 21 and the second side section 22 in a position opposite to the protruding section 24 in the left-and-right direction X.

In the first side section 21 and the second side section 22, respective recesses 25 recessed outward (toward an outer side surface S2 side) in the left-and-right direction X from the inner side surfaces S1 located on both sides of the counterweight 60 are continuously formed in the up-and-down direction Z. On each of the inner side surfaces S1 of the recesses 25, a fifth guide roller R5, a sixth guide roller R6, and a seventh guide roller R7 each for guiding the raising and lowering movement of the counterweight 60 abut from three directions.

Specifically, the fifth guide roller R5 abuts on the inner side surface S1 of the recess 25 on the rear direction Y2 side. The sixth guide roller R6 abuts on an outer side (bottom portion) of the inner side surface S1 of the recess 25 in the left-and-right direction X. The seventh guide roller R7 abuts on the inner side surface S1 of the recess 25 on a front direction Y1 side.

As such, the first side section 21 and the second side section 22 serve as guide rails for guiding the raising and lowering movement of the elevator section 30 and the counterweight 60.

The power receiving section 40 is raised and lowered together with the elevator section 30 and supplies the power received without contact from the feed line 50 to, for example, the transferring section 32. The power receiving section 40 is disposed between the first side section 21 and the second side section 22 in the left-and-right direction X, that is, inside the mast 20. This allows the power receiving section 40 to be disposed so as to prevent the power receiving section 40 from being exposed to the outside of the mast 20.

Further, the power receiving section 40 is disposed between the elevator section 30 and the counterweight 60 in the front-and-rear direction Y. More specifically, the power receiving section 40 is disposed between the fourth guide roller R4 and the coupling section 23.

The feed lines 50 are paired litz wires disposed in the mast 20 along the up-and-down direction Z. The feed lines 50 include respective feed wiring sections 51 disposed in feed positions P which are set between the elevator section 30 and the counterweight 60 in a plan view and in which power is supplied to the power receiving section 40. The feed wiring sections 51 are disposed in the feed positions P set between the elevator section 30 and the counterweight 60 in a plan view as described above, so that it is possible to dispose the feed lines 50 so as to prevent the feed lines 50 from interfering with the elevator section 30 and the counterweight 60. The feed wiring sections 51 are fixed to the feed positions P by respective fixing members 70 protruding from the inner side surfaces S1 of the first side section 21 and the second side section 22.

Here, as described above, the fireproof doors 8 are provided between the upper floor U and the middle floor M and between the middle floor M and the lower floor D. For fireproof measures, it is impossible to linearly dispose the feed lines 50 so that the feed lines 50 penetrate through the fireproof doors 8, and thus it is demanded to dispose the feed lines 50 so as to make a detour outside the fireproof doors 8.

In order to meet such a demand, in the article conveyance device 2, respective wiring paths 26 through which the feed lines 50 pass are provided in the first side section 21 and the second side section 22 of the mast 20. The wiring paths 26 are formed to penetrate through the first side section 21 and the second side section 22 so as to each pass between the first guide roller R1 and the counterweight 60 in a plan view. The wiring paths 26 may be, for example, through holes or notches (grooves) formed in the first side section 21 and the second side section 22.

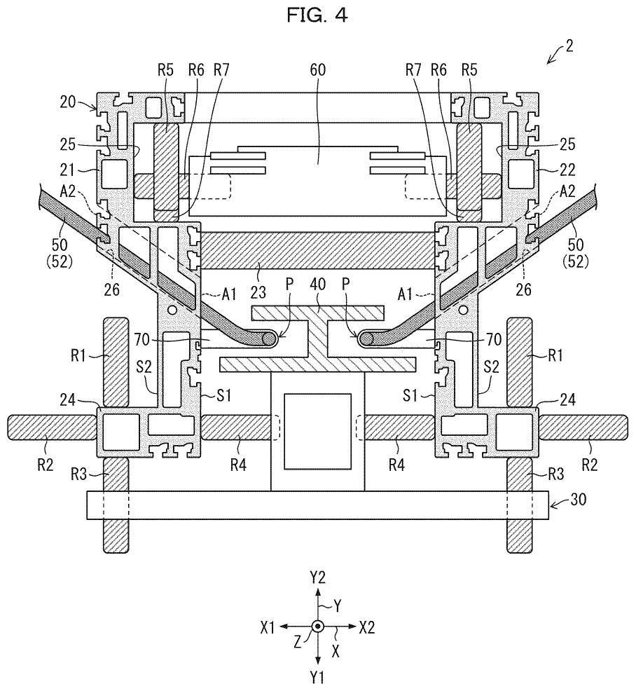

FIG. 4 is a plan view illustrating the wiring of bypass wiring sections 52 of the feed lines 50. As illustrated in FIG. 4, for example, in a case where the feed lines 50 are disposed so as to bypass the fireproof doors 8, the feed lines 50 are disposed so as to include respective bypass wiring sections 52 arranged from the feed positions P to the outsides of the first side section 21 and the second side section 22. The bypass wiring sections 52 are each disposed through the wiring path 26 located between the first guide roller R1 and the counterweight 60 in a plan view. This enables the bypass wiring section 52 to be disposed so as to prevent the bypass wiring section 52 from interfering with (contacting) the first guide roller R1 and the counterweight 60.

The bypass wiring sections 52 may be disposed obliquely with respect to the left-and-right direction X in a plan view. In other words, the wiring paths 26 may be formed obliquely with respect to the left-and-right direction X in a plan view. Specifically, the wiring paths 26 each include an inner opening A1 made on the inner side surface S1 of the mast 20 and an outer opening A2 made on the outer side surface S2 of the mast 20, and in the front-and-rear direction Y, the outer side opening A2 is disposed relatively on a rear direction Y2 side with respect to the inner side opening A1.

As such, the wiring paths 26 are each disposed obliquely with respect to the left-and-right direction X in a plan view so that the outer opening A2 is located further away from the first guide roller R1 than the inner opening A1. This enables each of the bypass wiring sections 52 to be disposed away from the first guide roller R1. Therefore, it is possible to ensure a sufficient clearance between the bypass wiring section 52 and the first guide roller R1 made in a case where the bypass wiring section 52 is extended to the outside of the mast 20.

Further, in the front-and-rear direction Y, the inner opening A1 is disposed relatively on the rear direction Y2 side with respect to the feed position P. This allows a bending angle of the bypass wiring section 52 made in a case where the bypass wiring section 52 is disposed from the feed position P to the inner opening A1 to be gentle. Therefore, the bending radius of the bypass wiring section 52 can be increased (for example, six times larger than the diameter of the feed line 50).

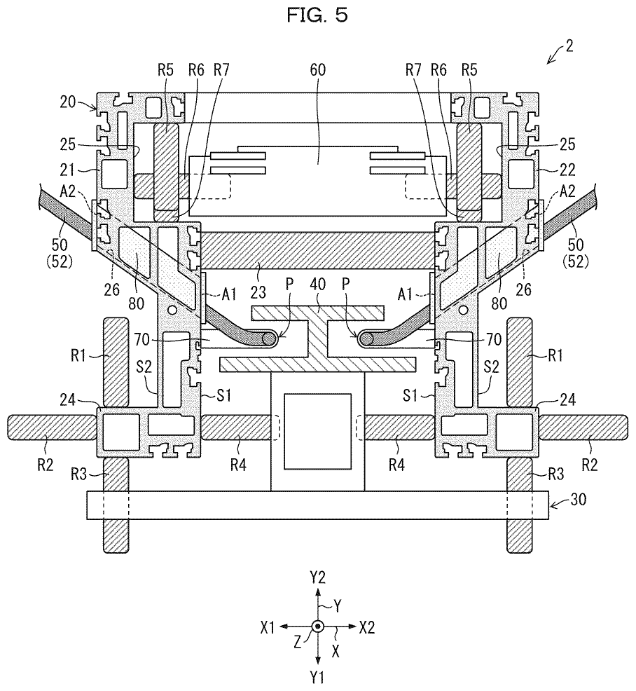

FIG. 5 is a plan view illustrating a configuration in which respective tubular sections 80 are attached to the wiring paths 26 illustrated in FIG. 4. As illustrated in FIG. 5, the article conveyance device 2 may include insulating tubular sections 80 inserted into the wiring paths 26.

The tubular sections 80, which are made of, for example, resin, are disposed along the respective wiring paths 26 obliquely with respect to the left-and-right direction X in a plan view. Disposing the bypass wiring sections 52 through the tubular sections 80 makes it possible to prevent the bypass wiring sections 52 from directly contacting the mast 20 and the corners of the mast 20.

### [Effects of Article Conveyance Device]

As described above, the article conveyance device 2 in accordance with the present embodiment includes: a mast 20 including a first side section 21 and a second side section 22 that are located opposite to each other; an elevator section 30 that is provided so as to be raisable and lowerable with respect to the mast 20 and that conveys a container 1; a power receiving section 40 that is disposed between the first side section 21 and the second side section 22 and that is raised and lowered together with the elevator section 30; and a feed line 50 that is disposed along the mast 20 and that supplies power to the power receiving section 40. At least one of the first side section 21 and the second side section 22 includes a wiring path 26 through which the feed line 50 passes.

In the article conveyance device 2 in accordance with the present embodiment, the power receiving section 40 is disposed between the first side section 21 and the second side section 22 of the mast 20 in which the feed line 50 is disposed. Therefore, the present embodiment enables the power receiving section 40 to be disposed inside the mast 20 so as to prevent the power receiving section 40 from being exposed to the outside of the mast 20, unlike the conventional art. Further, according to the present embodiment, the fact that the feed line 50 is disposed through the wiring path 26 of the mast 20 facilitates the wiring of the feed line 50.

In the embodiment described above, an example in which the conveyance device in accordance with the present disclosure is applied to an inter-floor conveyance device configured to convey an article across floors is described. It should be noted that the conveyance device in accordance with the present disclosure is applicable widely to any conveyance devices including masts for guiding the raising and lowering movement of elevator sections. The conveyance device in accordance with the present disclosure can be applied, for example, to a stacker crane or the like used in an automated warehouse.

Aspects of the present invention can also be expressed as follows:

A conveyance device in accordance with Aspect 1 of the present disclosure includes: a mast including a first side section and a second side section that are located opposite to each other; an elevator section that is provided so as to be raisable and lowerable with respect to the mast and that conveys an article; a power receiving section that is disposed between the first side section and the second side section and that is raised and lowered together with the elevator section; and a feed line that is disposed along the mast and that supplies power to the power receiving section, at least one of the first side section and the second side section including a wiring path through which the feed line passes.

According to the above configuration, the power receiving section is disposed between the first side section and the second side section of the mast in which the feed line is disposed, that is, inside the mast. Therefore, the above configuration enables the power receiving section to be disposed so as to prevent the power receiving section from being exposed to the outside of the mast. Further, according to the above configuration, the fact that the feed line is disposed through the wiring path of the mast facilitates the wiring of the feed line.

A conveyance device in accordance with Aspect 2 of the present disclosure may be configured, in Aspect 1 above, such that the conveyance device further includes a counterweight disposed opposite from the elevator section with the power receiving section interposed therebetween in a plan view, and the feed line includes a feed wiring section disposed in a feed position which is set between the elevator section and the counterweight in a plan view and in which power is supplied to the power receiving section.

The above configuration enables the feed line to be disposed so as to prevent the feed line from interfering with the elevator section and the counterweight.

A conveyance device in accordance with Aspect 3 of the present disclosure may be configured, in Aspect 2 above, such that the elevator section further includes a guide roller (first guide roller R1) abutting on an outer side surface of the mast, the feed line further includes a bypass wiring section arranged from the feed position to an outside of the first side section or an outside of the second side section, and the bypass wiring section is disposed so as to pass between the guide roller and the counterweight in a plan view.

The above configuration enables the bypass wiring section to be disposed so as to prevent the bypass wiring section from interfering with the guide roller and the counterweight.

A conveyance device in accordance with Aspect 4 of the present disclosure may be configured, in Aspect 3 above, such that with a direction in which the first side section and the second side section are located opposite to each other regarded as a width direction (left-and-right direction X), the bypass wiring section is disposed obliquely with respect to the width direction in a plan view.

The above configuration enables the bypass wiring section to be disposed so that the bypass wiring section is located away from the guide roller so as to prevent contact with the guide roller.

The present disclosure is not limited to the above-described embodiments, but can be altered by a skilled person in the art within the scope of the claims. The present disclosure also encompasses, in its technical scope of the present disclosure, any embodiment derived by appropriately combining technical means disclosed in differing embodiments. Further, it is possible to form a new technical feature by combining the technical means disclosed in the respective embodiments.

### REFERENCE SIGNS LIST

1 Container (article)
2 Article conveyance device (conveyance device)
20 Mast
21 First side section
22 Second side section
30 Elevator section
40 Power receiving section
50 Feed line
51 Feed wiring section
52 Bypass wiring section
60 Counterweight
P Feed position
R1 First guide roller
S1 Inner side surface
S2 Outer side surface
X Left-and-right direction (width direction)

1. A conveyance device comprising:
a mast including a first side section and a second side section that are located opposite to each other;
an elevator section that is provided so as to be raisable and lowerable with respect to the mast and that conveys an article;
a power receiving section that is disposed between the first side section and the second side section and that is raised and lowered together with the elevator section; and
a feed line that is disposed along the mast and that supplies power to the power receiving section,
at least one of the first side section and the second side section including a wiring path through which the feed line passes.

2. The conveyance device according to claim 1, further comprising a counterweight disposed opposite from the elevator section with the power receiving section interposed therebetween in a plan view,
the feed line including a feed wiring section disposed in a feed position which is set between the elevator section and the counterweight in a plan view and in which power is supplied to the power receiving section.

3. The conveyance device according to claim 2, wherein
the elevator section further includes a guide roller abutting on an outer side surface of the mast,
the feed line further includes a bypass wiring section arranged from the feed position to an outside of the first side section or an outside of the second side section, and
the bypass wiring section is disposed so as to pass between the guide roller and the counterweight in a plan view.

4. The conveyance device according to claim 3, wherein with a direction in which the first side section and the second side section are located opposite to each other regarded as a width direction, the bypass wiring section is disposed obliquely with respect to the width direction in a plan view.
